(19) United States
(12) Patent Application Publication
(10) Pub. No.: US 2026/0226321 A1
(43) Pub. Date: Aug. 6, 2026

(54) Electrically Conductive Adhesive Film

(71) Applicant: 3M INNOVATIVE PROPERTIES COMPANY, St. Paul, MN (US)

(72) Inventors: Taehoon Noh, Hwaseong-si (KR); Jeongwan Choi, Suwon-Si (KR); Junbeom Shin, Hwaseong-si (KR); Sang-Jun Mo, Suwon-si (KR); Jong-Pil Kim, Gyeonggi-do (KR)

(21) Appl. No.: 19/157,403

(22) PCT Filed: Feb. 19, 2024
(86) PCT No.: PCT/IB2024/051576

§ 371 Date: Aug. 18, 2025

Related U.S. Application Data
(60) Provisional application No. 63/486,669, filed on Feb. 24, 2023.

(51) Int. Cl. C09J 9/02; C09J 11/08; H05K 1/03; H05K 1/14

(52) U.S. Cl. CPC C09J 9/02; C09J 11/08; H05K 1/0393; H05K 1/144; H05K 2201/0329

(57) ABSTRACT

An electrically conductive adhesive film includes a base layer including a three-dimensional electrically conductive network of interconnected electrically conductive segments defining a three-dimensional network of interconnected voids where the network of the electrically conductive segments and voids extends between opposing first and second major surfaces of the base layer; an adhesive material disposed in the interconnected voids and extending between, and forming part of, the first and second major surfaces; and a plurality of electrically conductive first particles dispersed in the interconnected voids. At least some of the conductive segments and first particles can at least partially protrude through each of the first and second major surfaces of the base layer.

### TECHNICAL FIELD

The present description relates generally to electrically conductive adhesive films.

### BACKGROUND

An adhesive can include an electrically conductive fabric and/or electrically conductive particles to provide electrical conductivity.

### SUMMARY

In some aspects, the present description provides an electrically conductive adhesive film including a base layer including a three-dimensional electrically conductive network of interconnected electrically conductive segments defining a three-dimensional network of interconnected voids where the network of the electrically conductive segments and voids extends between opposing first and second major surfaces of the base layer, and an adhesive material disposed in the interconnected voids and extending between, and forming part of, the first and second major surfaces. The opposing first and second major surfaces of the base layer can be spaced apart in a thickness direction of the adhesive film by greater than about 30 microns. The adhesive film can include a plurality of electrically conductive first particles dispersed in the interconnected voids. At least some of the conductive segments and first particles can at least partially protrude through each of the first and second major surfaces of the base layer.

In some aspects, the present description provides an electrically conductive resiliently compressible adhesive film including an electrically conductive spongy layer having an uncompressed average thickness of greater than about 30 microns and being electrically conductive along at least a thickness direction thereof where the spongy layer includes an electrically conductive sponge material defining a plurality of interconnected pores, and an adhesive material disposed in the pores to form an adhesive layer comprising opposing external first and second major surfaces of the adhesive film. Portions of the conductive sponge material can protrude through each of the first and second major surfaces of the adhesive layer. The adhesive film can include a plurality of resiliently compressible polymeric particles dispersed in the pores, such that when the adhesive film is disposed between, and bonded to, first and second electrically conductive gold layers to form a compressible structure, an electrical resistance between the first and second gold layers is less than about 0.5 ohms and varies by less than about 50% when the compressible structure is compressed from no more than about 10 percent compression to least about 30 percent compression.

In some aspects, the present description provides an electrically conductive adhesive film including an electrically conductive porous spongy layer defining a plurality of interconnected pores and having an uncompressed average thickness of greater than about 30 microns. The spongy layer includes an electrically insulative sponge material coated with an electrically conductive material resulting in the spongy layer being electrically conductive along a thickness direction thereof and along each of mutually orthogonal first and second in-plane directions. An adhesive material can be disposed in the pores in the plurality of the interconnected pores to form an adhesive layer having opposing external first and second major surfaces of the adhesive film. Portions of the sponge material can protrude through each of the first and second major surfaces of the adhesive layer.

In some aspects, the present description provides an electrically conductive resiliently compressible adhesive film including an electrically conductive porous spongy layer defining a plurality of interconnected pores. The spongy layer can have an uncompressed average thickness of greater than about 30 microns. The spongy layer includes an electrically insulative sponge material coated with an electrically conductive material resulting in the spongy layer being electrically conductive along a thickness direction thereof and along each of mutually orthogonal first and second in-plane directions. The adhesive film can include a plurality of resiliently compressible polymeric particles dispersed in the pores.

These and other aspects will be apparent from the following detailed description. In no event, however, should this brief summary be construed to limit the claimable subject matter.

### BRIEF DESCRIPTION OF THE DRAWINGS

FIG. 1 is a schematic cross-sectional view of an electrically conductive adhesive film, according to some embodiments.

FIGS. 2-3 are images of top and cross-sectional views, respectively, of a three-dimensional electrically conductive network of interconnected electrically conductive segments defining a three-dimensional network of interconnected voids, according to some embodiments.

FIGS. 4-6 are images of top, bottom, and cross-sectional views, respectively, of an electrically conductive adhesive film, according to some embodiments.

FIG. 7 is a schematic cross-sectional view of an electrically conductive particle, according to some embodiments.

FIG. 8 is a schematic cross-sectional view of a hollow, compressible polymeric particle, according to some embodiments.

FIG. 9 is a schematic cross-sectional view of an electrically insulative material coated with an electrically conductive material, according to some embodiments.

FIG. 10 is a schematic cross-sectional view of an adhesive article, according to some embodiments.

FIGS. 11A-11C are schematic cross-sectional views of electrically conductive self-supporting support layers, according to some embodiments.

FIG. 12 is a plot of applied pressure and electrical resistance across a compressible structure versus percent compression, according to some embodiments.

FIGS. 13A-13B are plots of applied pressure and percent change in electrical resistance across a compressible structure versus percent compression, according to some embodiments.

FIG. 14 is a schematic cross-sectional view of an electronic device, according to some embodiments.

### DETAILED DESCRIPTION

In the following description, reference is made to the accompanying drawings that form a part hereof and in which various embodiments are shown by way of illustration. The drawings are not necessarily to scale. It is to be understood that other embodiments are contemplated and may be made without departing from the scope or spirit of the present description. The following detailed description, therefore, is not to be taken in a limiting sense.

According to some embodiments of the present description, a layer of an electrically conductive sponge material is utilized in an electrically conductive adhesive film. The sponge material can include interconnected electrically conductive segments defining a network of interconnected voids (pores). The adhesive film can include an adhesive material disposed in pores of the sponge material and extending between opposing major surfaces of the adhesive film, or an adhesive base layer of the adhesive film, so that adhesive material is present at major surfaces of the adhesive film or base layer. In some embodiments, portions of the conductive sponge material protrude through each of the major surfaces. It has been found that incorporating an electrically conductive sponge material as described further elsewhere herein in an adhesive film can result in high electrical conductivity (e.g., along at least a thickness direction or along each of three mutually orthogonal directions), low passive intermodulation (PIM), and/or desired mechanical strength of the adhesive film. In some embodiments, the adhesive film further includes electrically conductive particles (e.g., to further reduce electrical resistance) dispersed in the pores (e.g., by being dispersed in the adhesive material disposed in the pores) where at least some of the conductive particles at least partially protrude through each of the major surfaces of the adhesive layer. It has been found that having the electrically conductive sponge material and/or electrically conductive particles protruding through major surface(s) provide improved electrical contact with an adjacent surface, such as a metal surface (e.g., stainless steel or aluminum) having an oxide layer, for example, that the sponge and/or particles can at least partially penetrate.

The sponge material can be substantially compressible before the adhesive material is added to the pores. In some embodiments, adding the adhesive material results in the layer of sponge material no longer being substantially compressible. In some embodiments, resiliently compressible polymeric particles are dispersed in the pores (e.g., by being dispersed in the adhesive material disposed in the pores). Such resiliently compressible polymeric particles may provide a desired compressibility to the adhesive film. In has been found that when compressible polymeric particles are included in the pores, the electrical resistance across the adhesive layer is substantially stable when the adhesive layer is compressed over a range of 10 percent compression or less to 30 percent compression or more. In comparison the resistance of the conductive sponge material without adhesive and compressible particles, typically substantially decreases with compression over the same range. However, it is desired for some applications (e.g., some electronic device applications) that the resistance be substantially constant as the adhesive layer is compressed.

In some embodiments, before adhesive material is incorporated into the sponge material, the layer of sponge material can be compressed (e.g., by applying a pressure of no more than about 2 MPa) to less than about 50, 45, 40, 35, 30, or 25 percent of its uncompressed thickness. In some embodiments, the sponge material (without the adhesive material incorporated into the sponge material) has an apparent density (mass divided by uncompressed volume) of less than about 0.1, 0.09, 0.08, 0.07. 0.06, or 0.05 g/cm³. In some embodiments, adhesive material and resiliently compressible polymeric particles are disposed in pores of the sponge material to form an adhesive layer such that the adhesive layer can be compressed (e.g., by applying a pressure of no more than about 2 MPa) to less than about 80, 75, 70, 65, 60, 66, or 50 percent of its uncompressed thickness.

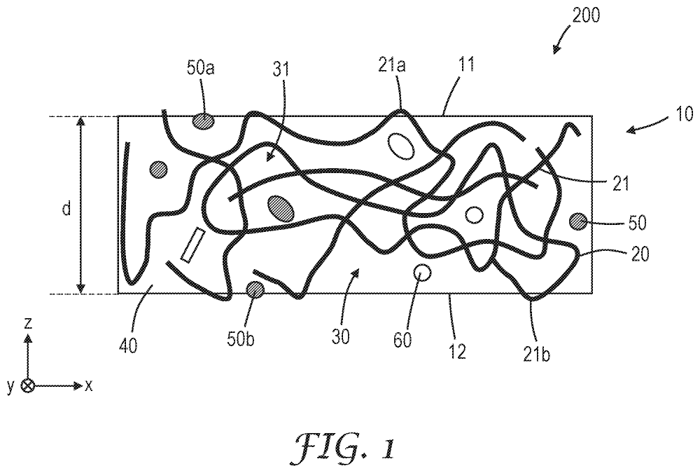

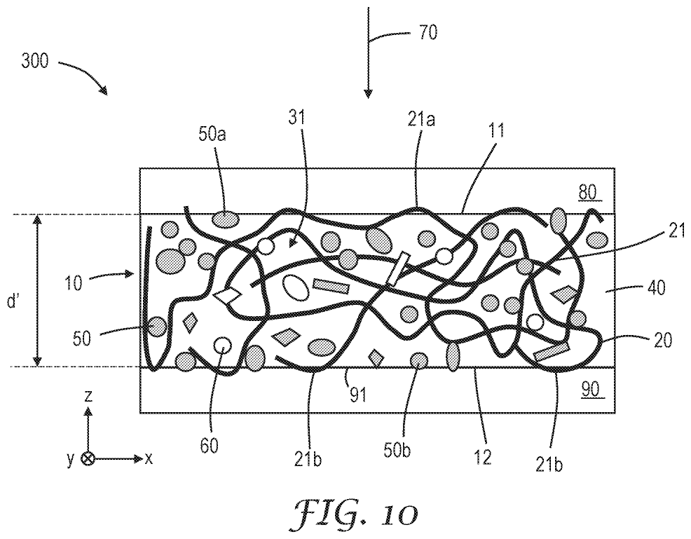

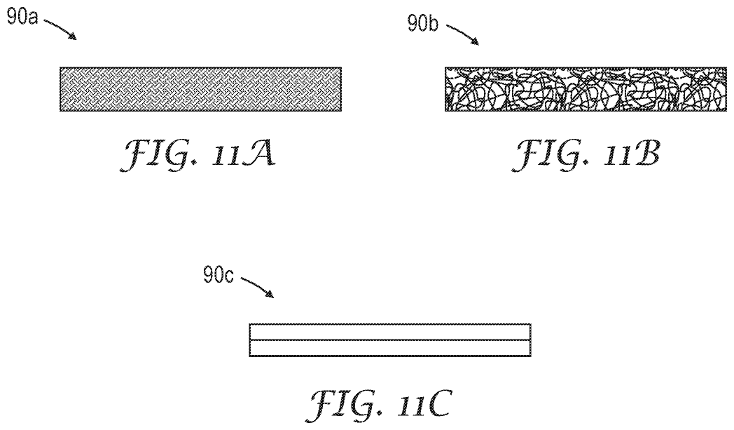

FIG. 1 is a schematic cross-sectional view of an electrically conductive adhesive film 200, according to some embodiments. In some embodiments, the electrically conductive adhesive film 200 includes a base layer 10 comprising a three-dimensional electrically conductive network 20 of interconnected electrically conductive segments 21 defining a three-dimensional network 30 of interconnected voids 31. The electrically conductive adhesive film 200 can optionally include one or more layers in addition to base layer 10 (see, e.g., FIG. 10). The network of the electrically conductive segments 21 and voids 31 extend between opposing first and second major surfaces 11 and 12 of the base layer 10 that can be spaced apart (by distance d) in a thickness direction (z-direction) of the adhesive film 200 by greater than about 30, or 40, or 50, or 60, or 70, or 80, or 90, or 100, or 110, or 120, or 130, or 140, or 150 microns. The distance d can be up to about 1500, 1000, 800, or 600 microns, for example. In some embodiments, the adhesive film 200 includes an adhesive material 40 disposed in the interconnected voids 31 and extending between, and forming part of, the first and second major surfaces 11 and 12. In some embodiments, the adhesive material 40 comprises greater than about 20, 30, 40, 50, 60, 70, 80, or 90 percent of a total surface area of each of the first and second major surfaces 11 and 12. In some embodiments, the adhesive material 40 fills greater than 20, 30, 40, 50, 60, 70, 80, or 90 percent of a total volume of the interconnected voids 31 between the first and second major surfaces 11 and 12. In some embodiments, the adhesive film 200 includes a plurality of electrically conductive first particles 50 dispersed in the interconnected voids 31. In some embodiments, the interconnected voids 31 between the first and second major surfaces 11 and 12 are substantially filled (e.g., greater than 50, 60, 70, 80, 90, or 95 percent of a total volume of the voids 31 can be filled) with the adhesive material 40 and the first particles 50. In some embodiments, adhesive film 200 further includes a plurality of resiliently compressible polymeric second particles 60 different from the first particles 50 and dispersed in the interconnected voids 31. In some embodiments, the interconnected voids 31 between the first and second major surfaces 11 and 12 are substantially filled with the adhesive material 40 and the first and second particles 50 and 60. In some embodiments, at least some of the conductive segments 21a, 21b and first particles 50a, 50b at least partially protrude through each of the first and second major surfaces 11, 12 of the base layer 10. It has been found that this can result in improved electrical contact with an adjacent surface. In some embodiments, at least some of the second particles 60 at least partially protrude through each of the first and second major surfaces 11, 12 of the base layer 10. In some embodiments, the second particles 60 are electrically conductive (e.g., electroplated, hollow, polymeric particles) and so this may also result in improved electrical contact with an adjacent surface.

The first and second particles can have respective first and second average particle sizes (e.g., the volume-median particle size D50) which can each be in a range of about 10 microns to about 200 microns, or about 15 microns to about 150 microns, or about 20 microns to about 100 microns, for example. The first and second particles can have any suitable shape. In some embodiments, the first and second particles are independently substantially spherical, irregularly shaped, or elongated along at least one direction (e.g., ellipsoid shape, rod shaped, etc.). For a spherical particle, the particle size of the particle can refer to the diameter of the particle. For a non-spherical (e.g., elongated) particle, the particle size can refer to the effective diameter (diameter of sphere having the same volume as the elongated particle) of the non-spherical particle. The first and/or second particles may comprise a plurality of different shapes. The first particles 50 and/or the second particles 60 may optionally be omitted.

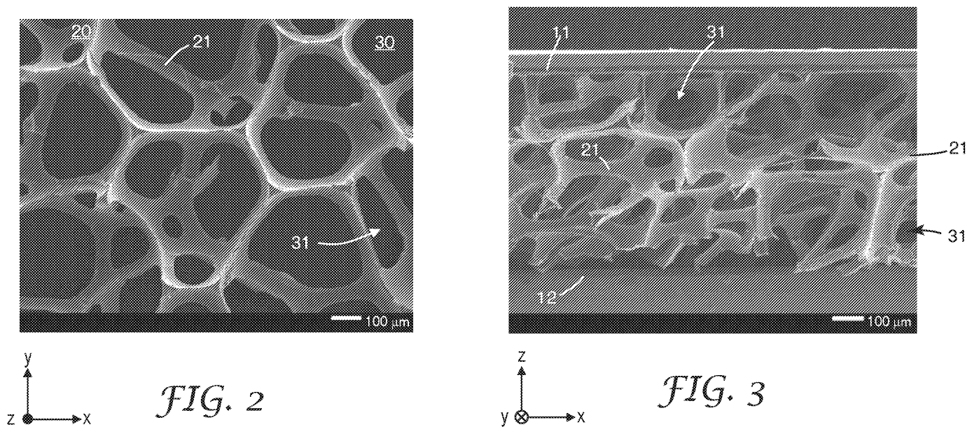

FIGS. 2-3 are top and cross-sectional views, respectively, of a three-dimensional electrically conductive network 20 of interconnected electrically conductive segments 21 defining a three-dimensional network 30 of interconnected voids 31, according to some embodiments. In some embodiments, the three-dimensional electrically conductive network 20 has an apparent density (mass divided by uncompressed volume) of less than about 0.2, 0.15, 0.1, 0.09, 0.08, 0.07. 0.06, or 0.05 g/cm³. The apparent density can be at least 0.02 or 0.01 g/cm³, for example. In some embodiments, the three-dimensional electrically conductive network 20, when the voids 31 are empty or at least partially filled with resiliently compressible particles, is such that in response to a first compressive force (e.g., force 70 depicted in FIG. 10), the network 20 is compressed by more than about 30%, or 35%, or 40%, or 45%, or 50% of its uncompressed average thickness, the network 20 regains at least about 60% of its uncompressed average thickness after the first compressive force is removed. In some embodiments, the network 20 regains at least about 65%, or 70%, or 75%, or 80%, or 85%, or 90%, or 95% of its uncompressed average thickness after the first compressive force is removed. The first compressive force can correspond to an applied pressure in a range of about 0.005 MPa to about 1.5 MPa, or about 0.01 to about 1.2 MPa, or about 0.02 to about 1 MPa, for example. Suitable materials for forming the network 20 of interconnected electrically conductive segments 21 include polymeric foams, for example, plated or otherwise coated (e.g., via sputtering) with one or more electrically conductive coatings. The polymeric foam can be an open cell polyurethane or polyethylene foam and may be a unitary structure (e.g., no seams and no separate elements bonded to one another via an adhesive). The polymeric foam may define a spongy layer. A “spongy layer” is generally a resiliently compressible layer (e.g., having a recovery after compression in a range described elsewhere herein) and typically includes a sponge material. A “sponge material” is generally a substantially porous (e.g., having an apparent density in a range described elsewhere herein) and resiliently compressible material. The polymeric foam can be coated (e.g., via electroplating or sputtering) with one or more metals such as nickel, copper, silver, gold, aluminum, or other metal or metal alloys. Suitable conductive sponges are available from HGP Advanced Materials Technology Corp., Ltd. (Guangxi, China) and from Hunan Ted New Material Co., Ltd. (Hunan, China) under the POROMETAL tradename, for example.

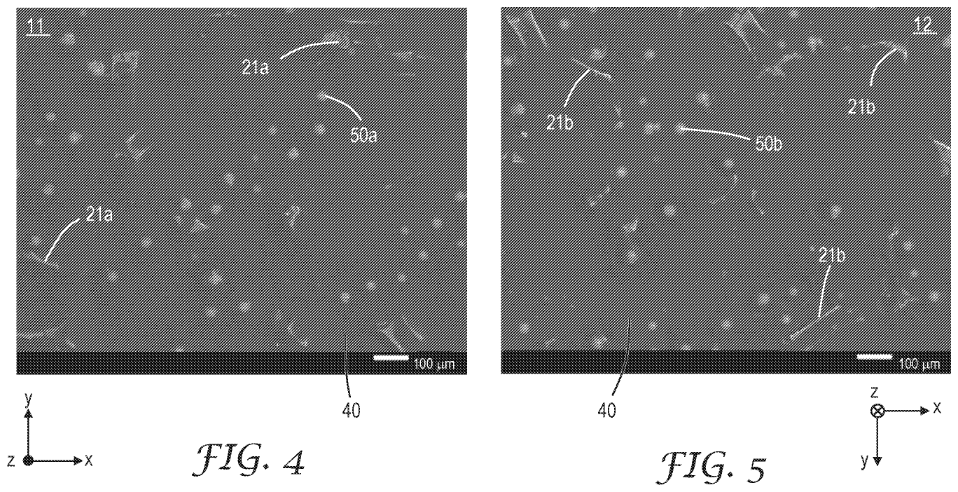

FIGS. 4-6 are top, bottom, and cross-sectional views, respectively, of an electrically conductive adhesive film, according to some embodiments. In some embodiments, at least some of the conductive segments 21a and first particles 50a at least partially protrude through the first major surface 11 (see, e.g., FIG. 4) and at least some of the conductive segments 21b and first particles 50b at least partially protrude through the second major surface 12 (see, e.g., FIG. 5).

The electrically conductive first particles 50 can be, for example, a solid metal particle or can be an electrically insulative (e.g., polymeric) particle coated with a metal.

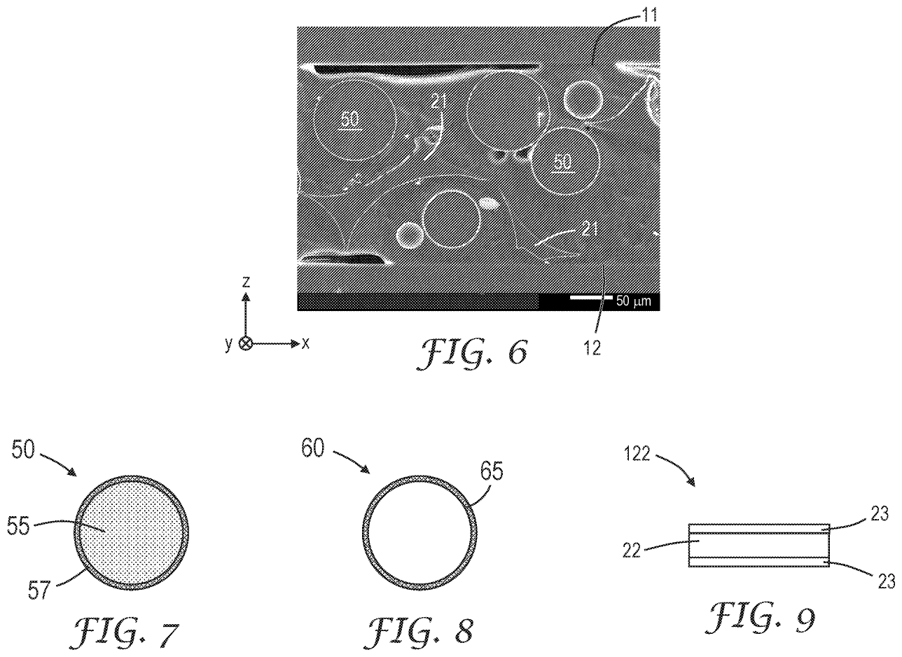

FIG. 7 is a schematic cross-sectional view of an electrically conductive particle 50, according to some embodiments. In some embodiments, the electrically conductive first particles 50 include insulative particles 55 coated with one or more conductive coatings 57. The insulative particles 55 can be polymeric particles, such as acrylic (e.g., polymethylmethacrylate) particles, for example. The insulative particles 55 can be solid particles or hollow particles, for example. The conductive coatings 57 can be or include nickel, copper, silver, gold, aluminum, or other metal or metal alloys. Suitable conductive particles are available from SNCTECH (Gwangju, Korea), for example.

In some embodiments, the adhesive film 200 further includes a plurality of resiliently compressible polymeric second particles 60 different from the first particles (e.g., having a different composition) and dispersed in the interconnected voids 31. The second particles 60 may be hollow particles and/or may be electrically insulative particles, for example.

FIG. 8 is a schematic cross-sectional view of a hollow, compressible polymeric particle 60, according to some embodiments. In some embodiments, at least some (e.g., greater than 30, 40, 50, 60, 70, 80, 90, or 95%) of the compressible polymeric second particles 60 are hollow. In some embodiments, at least some (e.g., greater than 30, 40, 50, 60, 70, 80, 90, or 95%) of the resiliently compressible polymeric second particles 60 are electrically insulative. In some embodiments, at least a majority (greater than 50%), or at least 60, 70, 80, 90, or 95% of the resiliently compressible polymeric second particles 60 are electrically insulative hollow particles. In some embodiments, at least some (e.g., greater than 30, 40, 50, 60, 70, 80, 90, or 95%) of the resiliently compressible polymeric second particles 60 are electrically conductive. For example, a hollow polymeric particle can be coated (e.g., via electroplating or sputtering) with a metal to provide an electrically conductive, resiliently compressible particle. Useful compressible particles are available from Matsumoto Yushi-Seiyaku Co., Ltd. (Osaka, Japan), for example.

Suitable materials that can be used for adhesive material 40 include acrylates such as acrylic pressure sensitive adhesive (PSA) materials. Acrylic PSAs can include two monomers having different glass transition temperatures (Tg). Useful low Tg monomers include, for example, isooctyl acrylate (IOA) which has a Tg of about −50° C. Useful high Tg monomers include, for example, acrylic acid (AA) which has a Tg of about 106° C. Other useful acrylates include 2-ethylhexyl methacrylate (2EHMA) which can lead to an increase in Tg and cross-linking density of the PSA. Other useful adhesive materials are described in U.S. Pat. No. 9,061,478 (Choi et al.) and International Pat. Appl. Pub. Nos. WO 2022/023830 (Noh et al.) and WO 2022/246682 (Gan et al.), for example. In some embodiments, the adhesive material is prepared by curing (e.g., by applying actinic radiation such as ultraviolet radiation) an adhesive formulation. The adhesive formulation, optionally mixed with particles 50 and/or 60, can be added to the voids 31 (e.g., by coating a conductive sponge material between release liners) and then subsequently cured to provide the adhesive film 200. Useful coating processes for applying the adhesive formulation are known in the art and include those described in International Pat. Appl. Pub. No. WO 2022/246682 (Gan et al.), for example.

In some embodiments, at least some of the conductive segments 21 at least partially protrude through the major surfaces 11 and 12 due, at least in part, to an uneven surface of the sponge material (e.g., higher elevations can protrude while lower elevations may not). In some embodiments, at least some of the particles (e.g., 50a, 50b) at least partially protrude through the major surfaces 11 and 12 due, at least in part, to a high loading of the particles resulting in particles near a surface partially pushing through the surface. In some embodiments, at least some of the conductive segments 21 and/or particles (e.g., 50a, 50b) at least partially protrude through the major surfaces 11 and 12 due, at least in part, to shrinkage of the adhesive formulation upon radiation curing.

FIG. 9 is a schematic cross-section view of a conductive material 122 including an electrically insulative material 22 coated with an electrically conductive material 23, according to some embodiments. The electrically insulative material 22 can be a sponge material or a fiber, for example. The electrically conductive material 23 can be one or more conductive coatings, such as one or more metallic coatings, for example. The electrically conductive segments 21 (see, e.g., FIG. 1) can be formed from an electrically insulative material 22 coated with an electrically conductive material 23, for example. In some embodiments, a unitary polymeric structure (e.g., a polymeric foam as described further elsewhere herein) is or includes the electrically insulative sponge material 22. In some embodiments, a unitary polymeric structure coated with one or more electrically conductive coatings comprises the three-dimensional electrically conductive network 30. The one or more electrically conducive coatings may cover at least about 50, 60, 70, 80, 90, or 95 percent of a total surface area of the unitary polymeric structure.

In some embodiments, an electrically conductive (e.g., resiliently compressible) adhesive film 200 (see, e.g., FIG. 1) includes an electrically conductive porous spongy layer 10 defining a plurality of interconnected pores 31 and having an uncompressed average thickness d of greater than about 30 microns (or d can be in a range described elsewhere herein). The electrically conductive porous spongy layer 10 is electrically conductive along at least a thickness direction (z-direction) thereof and may also be electrically conductive along at least one in-plane direction orthogonal to the thickness direction. In some embodiments, the spongy layer includes an electrically insulative sponge material 22 coated with an electrically conductive material 23 resulting in the spongy layer being electrically conductive along a thickness direction (z-direction) thereof and along each of mutually orthogonal first (x-direction) and second (y-direction) in-plane directions. In some embodiments, portions (21a, 21b) of the coated sponge material protrude through each of the first and second major surfaces of the adhesive layer.

In some embodiments, an adhesive material 40 is disposed in the pores in the plurality of the interconnected pores to form an adhesive layer comprising opposing external first and second major surfaces 11 and 12 of the adhesive film 200. In some embodiments, portions (21a, 21b) of the sponge material protrude through each of the first and second major surfaces of the adhesive layer 40. In some embodiments, the electrically conductive adhesive film 200 further includes a plurality of resiliently compressible polymeric particles 60 dispersed in the pores 31. The plurality of resiliently compressible polymeric particles 60 can be a plurality of electrically insulative resiliently compressible polymeric particles. In other embodiments, the resiliently compressible polymeric particles 60 can be electrically conductive (e.g., by including an electrically conductive coating). In some embodiments, the electrically conductive adhesive film 200 further includes a plurality of electrically conductive first particles 50 dispersed in the adhesive material. The first particles 50 and the resiliently compressible polymeric particles 60 can have different compositions. In some embodiments, at least some of the first particles (50a, 50b) at least partially protrude through each of the first and second major surfaces 11 and 12 of the adhesive film 200.

In some embodiments, an electrically conductive resiliently compressible adhesive film 200 includes a plurality of resiliently compressible polymeric particles 60 dispersed in the pores. The resiliently compressible polymeric particles 60 may result in the adhesive film 200 being resiliently compressible. In some embodiments, adhesive film 200 further includes an adhesive material 40 is disposed in the pores in the plurality of the interconnected pores to form an adhesive layer comprising opposing external first 11 and second 12 major surfaces of the adhesive film, where portions (21a, 21b) of the conductive sponge material may protrude through each of the first and second major surfaces 11 and 12 of the adhesive layer 40. In some embodiments, separate conductive adhesive layers are disposed opposite sides of the electrically conductive porous spongy layer 10. In some embodiments, the adhesive material 40 fills greater than about 30, 40, 50, 60, 70, 80 percent of a total volume of the interconnected pores between the first and second major surfaces 11 and 12. In some embodiments, the adhesive material 40 and the particles 60 collectively fills greater than about 30, 40, 50, 60, 70, 80, 90, or 95 percent of a total volume of the interconnected pores between the first and second major surfaces 11 and 12. In some embodiments, at least a majority (greater than 50% or in a range described elsewhere herein) of the resiliently compressible polymeric particles 60 are electrically insulative. In some embodiments, the adhesive film 200 further includes a plurality of electrically conductive first particles 50 dispersed in the adhesive material 40, where at least some of the first particles (50a, 50b) at least partially protrude through each of the first and second major surfaces 11 and 12 of the adhesive film. In some embodiments, the resiliently compressible polymeric particles 60, but not the first particles 50, are hollow.

FIG. 10 is a schematic cross-sectional view of an adhesive article 300, according to some embodiments. Adhesive article 300 can be an adhesive film, a tape, and/or a compressible structure, for example. Adhesive article 300 can correspond to adhesive film 200 with optional additional layers 80 and/or 90 included. In some embodiments, one of the layers 80 and 90 is omitted. In some embodiments, at least one of layers 80 and 90 is a release liner. In some embodiments, at least one of layers 80 and 90 is a gold layer. In some embodiments, at least one of layers 80 and 90 comprises at least one or more of stainless steel, aluminum, magnesium, gold, silver, titanium, tungsten, and alloys thereof. In some embodiments, at least one of the layers 80 and 90 is a self-supporting support layer. A self-supporting layer is a layer that does not need additional layer(s) to support the layer. Polymeric self-supporting layers typically have an average thickness of greater than about 3 microns, for example. Polymeric coatings having an average thickness less than about a micron, for example, are typically not self-supporting since additional layers are needed to support such thin coatings.

A compressive force 70 is schematically illustrated in FIG. 10. The base layer 10 can have an average thickness d′ when the compressive force 70 is applied. In some embodiments, the adhesive film 200 includes a plurality of resiliently compressible polymeric particles 60 such that when, in response to a first compressive force 70, the base layer 10 is compressed by more than about 30% of its uncompressed average thickness d (i.e., [d−d′]/d×100% is more than about 30%, where d′ is the compressed thickness of the base layer), the base layer regains at least about 60%, or 65%, or 70%, or 75%, or 80%, or 85%, or 90%, or 95% of its uncompressed average thickness after the first compressive force is removed. In some embodiments, the base layer 10 regains any of these percentages of its uncompressed average thickness after the first compressive force 70 is removed when the base layer 10 is compressed by more than about 35%, or 40%, or 45%, or 50% of its uncompressed average thickness d in response to the first compressive force 70. For example, in some embodiments, in response to the first compressive force 70, the base layer 10 is compressed by more than about 40% of its uncompressed average thickness d, the base layer regains at least about 70% of its uncompressed average thickness after the first compressive force 70 is removed. The first compressive force 70 can correspond to an applied pressure (applied force 70 divide by area of a major surface) in a range described elsewhere herein. In some embodiments, an applied pressure of no more than about 2 MPa, or no more than about 1.5 MPa, or no more than about 1 MPa, or no more than about 0.8 MPa compresses the base layer 10 by more than about 30%, 35%, or 40%, or 45%, or 50% of its uncompressed average thickness.

In some embodiments, the electrically conductive adhesive film 200, 300 includes at least one release layer 80 and/or 90 disposed on and in contact with one of the first and second major surfaces of the base layer 10 such that removing the release layer from the base layer results in no, or very little, damage to the base layer 10. Very little damage to the base layer 10 refers to damage not readily visible when the base layer 10 is viewed with the unaided eye of a person with 20/20 vision under normal room lighting conditions. The lighting conditions can be taken to be under the Standard Illuminant D65 as defined by the International Commission on Illumination (CIE). Suitable release layers include polyethylene terephthalate (PET) films release treated with silicone, for example. In some embodiments, each of layers 80 and 90 is a release layer (e.g., article 300 can be a double-sided conductive tape).

In some embodiments, layer 90, for example, is an electrically conductive self-supporting support layer. In some embodiments, an adhesive tape 300 includes the electrically conductive resiliently compressible adhesive film 200 bonded to an electrically conductive self-supporting support layer 90 electrically conductive in the thickness direction (z-direction) and each of mutually orthogonal in-plane first and second directions (x- and y-directions), where an electrically conductive major surface 91 of the support layer 90 makes electrical and physical contact with portions 21b of the electrically conductive sponge material 122. In some embodiments, an electrically conductive adhesive film 300 includes an electrically conductive self-supporting support layer 90 electrically conductive in the thickness direction (z-direction) and each of mutually orthogonal in-plane first and second directions (x- and y-directions), where the support layer 90 is disposed on and bonded to the base layer 10 so that an electrically conductive major surface 91 of the support layer 90 makes electrical and physical contact with some of the conductive segments 21b and with at least one 50b of the electrically conductive first particles 50. The at least one 50b of the electrically conductive first particles 50 can include a plurality of the electrically conductive first particles 50. In some embodiments, layer 90 is an electrically conductive self-supporting support layer and layer 80 is a release layer (e.g., article 300 can be a single-sided conductive tape).

The support layer 90 can be or include a conductive foil or a conductive fabric, for example. The support layer 90 can be a multilayer electrically conductive film (e.g., including one or more foil layers disposed on a substrate), for example.

FIGS. 11A-11C are schematic cross-sectional views of electrically conductive self-supporting support layers, according to some embodiments. Support layer 90a can be an electrically conductive woven fabric, support layer 90b can be a non-woven support layer, and support layer 90c can be a multilayer conductive film (e.g., including multiple foil layers, at least one foil layer and at least one conductive fabric layer, or at least one foil layer disposed on a substrate). In some embodiments, the self-supporting support layer 90, 90a, 90b, 90c comprises one or more of an electrically conductive foil and a fabric. In some embodiments, the electrically conductive fabric 90a comprises a plurality of woven electrically conductive fibers. In some embodiments, the electrically conductive fabric 90b comprises a plurality of non-woven electrically conductive fibers. In some embodiments, the electrically conductive fibers (of the woven or non-woven fabric) comprise electrically insulative fibers (e.g., corresponding to insulative material 22) coated with one or more conductive coatings (e.g., corresponding to coating 23). In some embodiments, the electrically conductive foil comprises one or more of copper, metal plated copper, nickel plated copper, nickel alloy plated copper, tin plated copper, gold plated copper, nickel, a nickel alloy, and a multilayer electrically conductive film.

In some embodiments, the self-supporting support layer 90, 90a, 90b, 90c has an average thickness of greater than about 4, or 6, or 8, or 10, or 20, or 50, or 75, or 100, or 125, or 150, or 175, or 200 microns. The average thickness can be up to about 5, 3, 2, 1, or 0.5 mm, for example.

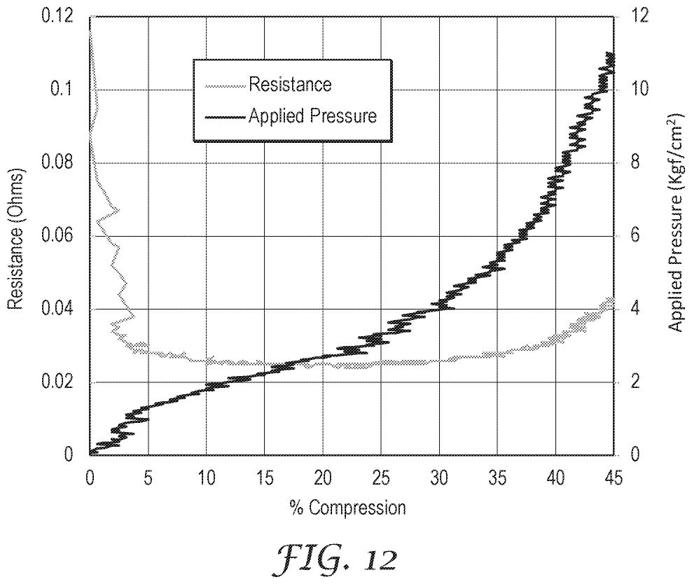

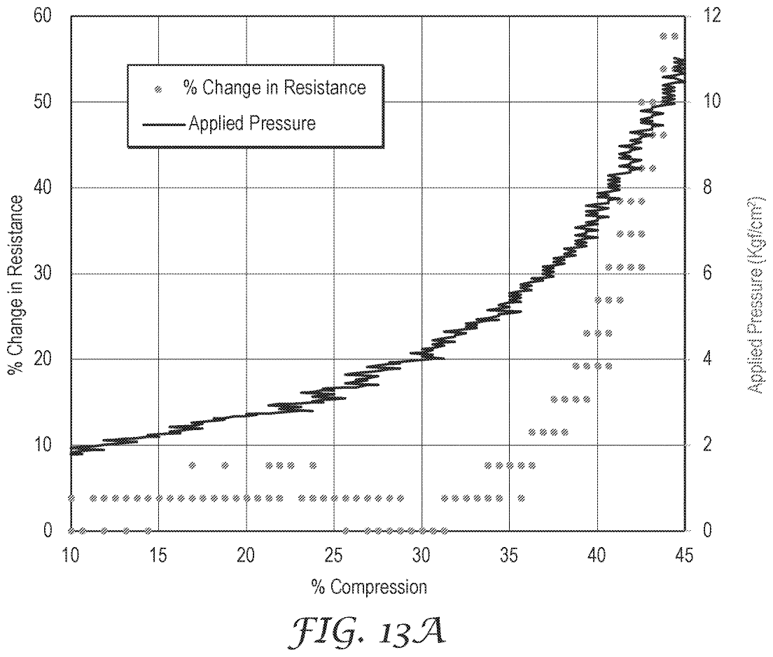

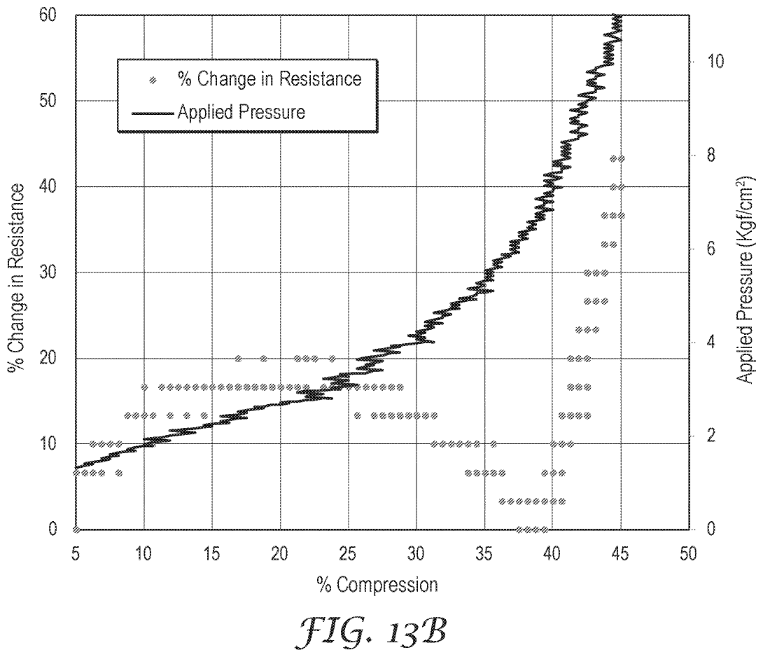

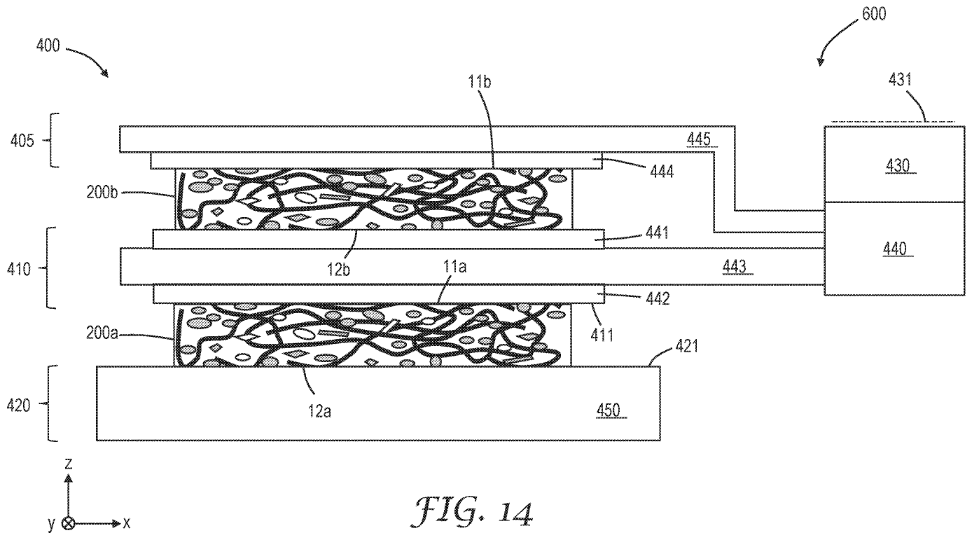

FIG. 12 is a plot of applied pressure and electrical resistance across a compressible structure versus percent displacement, according to some embodiments. FIGS. 13A-13B are plots of applied pressure and percent change in resistance across a compressible structure versus percent compression of the compressible structure, according to some embodiments. FIG. 13A shows the percent change in resistance from an initial 10 percent compression when the compression is further increased from 10%, and FIG. 13B shows the percent change in resistance from an initial 5 percent compression when the compression is further increased from 5%. FIGS. 12 and 13A-13B show illustrative results for Example 19 which is described further elsewhere herein.

In some embodiments, an electrically conductive resiliently compressible adhesive film 200 (see, e.g., FIGS. 1 and 10) includes an electrically conductive spongy layer 10 having an uncompressed average thickness d of greater than about 30 microns (or d can be in a range described elsewhere herein) and being electrically conductive along at least a thickness direction (z-direction) thereof. The spongy layer 10 includes an electrically conductive sponge material 20 defining a plurality of interconnected pores 31. In some embodiments, an adhesive material 40 disposed in the pores 31 to form an adhesive layer comprising opposing external first and second major surfaces 11 and 12 of the adhesive film, where portions (21a, 21b) of the sponge material protrudes through each of the first and second major surfaces 11 and 12 of the adhesive layer. In some embodiments, the adhesive film 200 includes a plurality of resiliently compressible polymeric particles 60 dispersed in the pores 31, such that when the adhesive film 200 is disposed between, and bonded to, first and second electrically conductive gold layers (e.g., layers 80 and 90 can be gold layers) to form a compressible structure (e.g., corresponding to adhesive article 300), an electrical resistance between the first and second gold layers is less than about 0.5 ohms and varies by less than about 50% when the compressible structure is compressed from no more than about 10 percent compression to least about 30, or 35, or 40, or 45, or 50, or 55 percent compression. 10 percent compression, for example, means that [d−d′]/d×100% is 10 percent. In some embodiments, the electrical resistance between the first and second gold layers varies less than about 45%, or 40%, or 35%, or 30%, or 25%, or 20%, or 15%, or 10%, or 5% when the compressible structure is compressed in any of these ranges. For example, in some embodiments, the electrical resistance between the first and second gold layers varies by less than about 25% when the compressible structure is compressed from about 5 percent compression to about 40 percent compression, and/or varies by less than about 10% when the compressible structure is compressed from about 10 percent compression to about 35 percent compression. The electrical resistance between the first and second gold layers can be less than about 0.5 ohms at 0, 5, or 10 percent compression, for example. The electrical resistance between the first and second gold layers can be less than about 0.4, 0.3, 0.2, or 0.1 ohms at each of these compressions. In some embodiments, the electrical resistance between the first and second gold layers is less than about 0.1, 0.08, 0.06, 0.05, or 0.04 ohms at each compression in the range of no more than about 10 percent compression to at least about 30 percent compression.

In some embodiments of the electrically conductive resiliently compressible adhesive film 200, the resiliently compressible polymeric particles 60 are electrically insulative, as described further elsewhere herein. In some embodiments, the electrically conductive resiliently compressible adhesive film 200 further includes a plurality of electrically conductive particles 50 dispersed in the adhesive layer 40, where at least some of the electrically conductive particles (50a, 50b) at least partially protrude through each of the first and second major surfaces 11 and 12 of the adhesive film 200, as described further elsewhere herein.

FIG. 14 is a schematic cross-sectional view of an electronic device 400, according to some embodiments. The electronic device 400 can be a mobile device such as a cell phone. The electronic device 400 can include a display 600. In some embodiments, the electronic device 400 includes at least one adhesive film 200a, 200b that corresponds to adhesive film 200, for example.

In some embodiments, an electronic device 400 includes a first electrically conductive adhesive film 200a (corresponding to adhesive film 200) disposed between, and bonding and electrically connecting to, first and second electrically conductive components 410 and 420 of the electronic device 400. In some embodiments, at least one of the first and second electrically conductive components 410 and 420 includes an electrically conductive outermost surface 421 that makes electrical and physical contact with one of the first and second major surfaces of the base layer 10 of the first electrically conductive adhesive film 200a and includes at least one or more of stainless steel, aluminum, magnesium, gold, silver, titanium, tungsten, and alloys thereof. In some embodiments, the first and second electrically conductive components 410 and 420 comprise respective electrically conductive first and second outermost surfaces 411 and 421 that comprise respective gold and one of stainless steel, aluminum, magnesium, gold, silver, titanium, tungsten, and alloys thereof and make electrical and physical contact with the respective first and second major surfaces of the base layer of the first electrically conductive adhesive film 200a.

In some embodiments, a display 600 includes a display panel 430 configured to form a viewable image 431 and drivable by receiving electrical signals from an electronic circuit 440. The electronic circuit 440 includes a first flexible circuit 410 including electrically conductive first and second traces 441 and 442 disposed on opposing major sides of a first flexible film 443; an electrically conductive substrate 450 including an electrically conductive outermost surface 421; and a first of the electrically conductive resiliently compressible adhesive film 200a disposed between the first flexible circuit 410 and the electrically conductive substrate 420, such that: the first major surface 11a of the first adhesive film 200a is bonded, and makes physical and electrical contact, to the second trace of the first flexible circuit 410; and the second major surface 12a of the first adhesive film 200a is bonded, and makes physical and electrical contact, to the electrically conductive outermost surface 411 of the electrically conductive substrate. In some embodiments, the electrically conductive outermost surface 421 comprises at least one or more of stainless steel, aluminum, magnesium, gold, silver, titanium, tungsten, and alloys thereof.

In some embodiments, the electronic circuit 440 includes a second flexible circuit 405 including an electrically conductive third trace 444 disposed on a major side of a second flexible film 445. In some embodiments, the display 600 further includes a second of the electrically conductive resiliently compressible adhesive film 200b disposed between the first and second flexible circuits 410 and 405, such that: the first major surface 11b of the second adhesive film 200b is bonded, and makes physical and electrical contact, to the third trace 444 of the second flexible circuit 405; and the second major surface 12b of the second adhesive film 200b is bonded, and makes physical and electrical contact, to the first conductive trace 441 of the first flexible circuit 410. In some embodiments, the adhesive films 200a, 200b provide electrical connection between circuits 405, 410 and component 420 such that the electrical resistances across the adhesive films 200a, 200b remain approximately constant over a range of compression of the adhesive films 200a, 200b as described further elsewhere herein (see, e.g., FIGS. 12 and 13A-13B).

### EXAMPLES

All parts, percentages, ratios, etc. in the examples are by weight, unless noted otherwise.

### Materials

| Abbreviation | Description | Supplier |
|---|---|---|
| PCN-100 | Nickel coated PMMA powder, | SNCTECH, |
| | D50 of 0.10 mm | Gwangju, |
| | | Korea |
| P30 | Nickel coated powder, D50 | SNCTECH, |
| | of 0.03 mm | Gwangju, |
| | | Korea |
| MFL-SEVEN | Microspheres, particle size | Matsumoto |
| | 20-40 microns, specific | Yushi- |
| | gravity 0.14 g/cc | Seiyaku, |
| | | Japan |
| MFL-100MCA | Microspheres, particle | Matsumoto |
| | size 60-70 microns, | Yushi- |
| | specific gravity 0.12 g/cc | Seiyaku, |
| | | Japan |
| IOA | Isooctyl acrylate | 3M, Belgium |
| | | (or USA) |
| 2EHMA | 2-Ethylhexyl methacrylate | Mitsubishi |
| | | Gas |
| | | Chemical, |
| | | Japan |
| AA | Acrylic acid | BASF, |
| | | Germany |
| IRGACURE 651 | 2,2-dimethoxy-1,2-diphenyl- | IGM Resisns, |
| | ethanone (photoinitiator) | China |
| HDDA | 1,6-hexanediol diacrylate | SK Cytec, |
| | (crosslinker) | Korea |
| HGP-H06 | Conductive sponge, thickness | HGP, China |
| | 0.492 mm, apparent density | |
| | 0.063 g/cc | |
| HGP-R06 | Conductive sponge, thickness | HGP, China |
| | 0.482 mm, apparent density | |
| | 0.049 g/cc | |
| PRM-CF006 | POROMETAL conductive | Hunan Ted |
| | sponge, thickness 0.456 | New Material |
| | mm, apparent density | Co., Ltd., |
| | 0.044 g/cc | China |
| PRM-CF010 | POROMETAL conductive | Hunan Ted |
| | sponge, thickness 0.960 | New Material |
| | mm, apparent density | Co., Ltd., |
| | 0.038 g/cc | China |

Pre-polymerized syrup was prepared by adding 0.04 pph of photoinitiator (IRGACURE 651) into 100 parts by weight of acrylate (IOA) and conducting low intensity radiation polymerization until the temperature was raised by about 3 to 10° C. An acrylic prepolymer syrup was prepared by mixing the pre-polymerized syrup, acrylate and additives as given in the table below. Polyethylene terephthalate support films release treated with silicone were used as release liners. The thickness of the release liners were 0.05 mm and 0.075 mm. The acrylic prepolymer syrup was coated onto the conductive sponge indicated in the table below between the release liners by using dual rollers to embed the acrylic prepolymer syrup into the conductive sponge. The acrylic prepolymer syrup was cured by applying ultraviolet (UV) radiation. The total energy density of the UV radiation was controlled to be between 1000 mJ/cm² and 3000 mJ/cm².

Peel strength of the resulting adhesive films from stainless steel from opposite sides of the adhesive films were measured as generally described in ASTM D1000-17, “Standard Test Methods for Pressure-Sensitive Adhesive-Coated Tapes Used for Electrical and Electronic Applications”. A 180 degree peel with a peel speed of about 305 mm/min was used. Results are provided in the table below.

Electrical resistance of the adhesive films in the thickness direction between gold surfaces (Au/Au) and between gold and stainless steel surfaces (Au/SS) were measured as follows. Two strips of the conductive tape were placed near a center of the electrodes on a PCB board. The size of PCB board was 25 mm×50 mm and the thickness was 1.6 mm. The electrodes on the board were 10 mm wide. The distance between electrodes was 30 mm. After initial hand lamination to provide a 10 mm×10 mm contact area between the tape and electrodes, another PCB board was attached on the other side of the tape, the size of this board was 10 mm×50 mm. Then, a 2 kg rubber roller was applied across the board to simulate a typical manufacturing process that might be used to apply the tapes to a surface. After 20 minutes of dwell time, the direct current (DC) resistance between the electrodes was measured with a micro-ohm meter. Results are reported in the following table.

| | | | | | | 180 | 180 | | |
|---|---|---|---|---|---|---|---|---|---|
| | | | | | | deg. | deg. | | |
| | | | | | | peel, | peel, | | |
| | | Monomer | | | | Top | Bottom | Resist. | Resist. |
| | | ratio | HDDA | Powder | Thick. | side | side | Au/Au | Au/SS |
| Ex. | Sponge | (IOA:AA:2EHMA) | (pph) | Content | (μm) | (N/mm) | (N/mm) | (Ω) | (Ω) |
| 1 | HGP- | 92:08:00 | 0.10 | | 284 | 0.54 | 0.55 | 0.01 | 0.04 |
| | H06 | | | | | | | | |
| 2 | HGP- | 92:08:00 | 0.20 | | 282 | 0.53 | 0.59 | 0.01 | 0.04 |
| | H06 | | | | | | | | |
| 3 | HGP- | 90:10:00 | 0.20 | | 309 | 0.52 | 0.50 | 0.01 | 0.07 |
| | H06 | | | | | | | | |
| 4 | HGP- | 88:10:02 | 0.10 | | 260 | 0.60 | 0.64 | 0.01 | 0.06 |
| | H06 | | | | | | | | |
| 5 | HGP- | 88:10:02 | 0.10 | P30, | 296 | 0.51 | 0.55 | 0.01 | 0.06 |
| | H06 | | | 6.25 pph | | | | | |
| 6 | HGP- | 92:08:00 | 0.2 | P30, | 295 | 0.55 | 0.57 | 0.01 | 0.09 |
| | H06 | | | 18.75 pph | | | | | |
| 7 | HGP- | 88:10:02 | 0.1 | PCN-100, | 292 | 0.63 | 0.67 | 0.01 | 0.02 |
| | H06 | | | 25 pph | | | | | |
| 8 | HGP- | 88:10:02 | 0.1 | PCN-100, | 274 | 0.62 | 0.66 | 0.01 | 0.02 |
| | H06 | | | 50 pph | | | | | |
| 9 | HGP- | 92:08:00 | 0.2 | PCN-100, | 268 | 0.40 | 0.57 | 0.01 | 0.03 |
| | H06 | | | 50 pph | | | | | |
| 10 | PRM- | 88:10:02 | 0.1 | | 199 | 0.54 | 0.37 | 0.01 | 0.03 |
| | CF010 | | | | | | | | |
| 11 | PRM- | 88:10:02 | 0.1 | | 188 | 0.67 | 0.65 | 0.01 | 0.05 |
| | CF006 | | | | | | | | |
| 12 | PRM- | 88:10:02 | 0.1 | PCN-100, | 200 | 0.72 | 0.58 | 0.01 | 0.04 |
| | CF006 | | | 50 pph | | | | | |
| 13 | HGP- | 88:10:02 | 0.1 | | 195 | 0.60 | 0.70 | 0.01 | 0.03 |
| | H06 | | | | | | | | |
| 14 | HGP- | 88:10:02 | 0.1 | PCN-100, | 199 | 0.22 | 0.26 | 0.01 | 0.01 |
| | H06 | | | 50 pph | | | | | |
| 15 | HGP- | 88:10:02 | 0.1 | MFL | 276 | 0.61 | 0.60 | 0.02 | 0.13 |
| | R06 | | | SEVEN, | | | | | |
| | | | | 10 pph | | | | | |
| 16 | PRM- | 88:10:02 | 0.1 | MFL- | 316 | 0.51 | 0.46 | 0.02 | 0.05 |
| | CF010 | | | 100MCA, | | | | | |
| | | | | 10 pph | | | | | |
| 17 | PRM- | 88:10:02 | 0.1 | | 372 | 0.74 | 0.63 | 0.03 | 0.11 |
| | CF010 | | | | | | | | |
| 18 | PRM- | 88:10:02 | 0.1 | PCN-100, | 408 | 0.69 | 0.62 | 0.02 | 0.05 |
| | CF010 | | | 50 pph | | | | | |
| 19 | PRM- | 88:10:02 | 0.1 | MFL- | 400 | 0.59 | 0.57 | 0.03 | 0.09 |
| | CF010 | | | 100MCA, | | | | | |
| | | | | 10 pph | | | | | |

FIGS. 4-6 are images of top, bottom, and cross-sectional views, respectively, of the adhesive film of Example 12. For some samples, percent compression and resistance across the thickness of the adhesive film between gold layers were measured for various applied pressures. Results are shown in FIGS. 12, 13A, and 13B for the adhesive film of Example 19.

Terms such as “about” will be understood in the context in which they are used and described in the present description by one of ordinary skill in the art. If the use of “about” as applied to quantities expressing feature sizes, amounts, and physical properties is not otherwise clear to one of ordinary skill in the art in the context in which it is used and described in the present description, “about” will be understood to mean within 10 percent of the specified value. A quantity given as about a specified value can be precisely the specified value. For example, if it is not otherwise clear to one of ordinary skill in the art in the context in which it is used and described in the present description, a quantity having a value of about 1, means that the quantity has a value between 0.9 and 1.1, and that the value could be 1.

Terms such as “substantially” will be understood in the context in which they are used and described in the present description by one of ordinary skill in the art. If the use of “substantially” with reference to a property or characteristic is not otherwise clear to one of ordinary skill in the art in the context in which it is used and described in the present description and when it would be clear to one of ordinary skill in the art what is meant by an opposite of that property or characteristic, the term “substantially” will be understood to mean that the property or characteristic is exhibited to a greater extent than the opposite of that property or characteristic is exhibited.

All references, patents, and patent applications referenced in the foregoing are hereby incorporated herein by reference in their entirety in a consistent manner. In the event of inconsistencies or contradictions between portions of the incorporated references and this application, the information in the preceding description shall control.

Descriptions for elements in figures should be understood to apply equally to corresponding elements in other figures, unless indicated otherwise. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations, or variations, or combinations of the specific embodiments discussed herein. Therefore, it is intended that this disclosure be limited only by the claims and the equivalents thereof.

1. An electrically conductive adhesive film comprising:
a base layer comprising a three-dimensional electrically conductive network of interconnected electrically conductive segments defining a three-dimensional network of interconnected voids, the network of the electrically conductive segments and voids extending between opposing first and second major surfaces of the base layer spaced apart in a thickness direction of the adhesive film by at least 30 microns;
an adhesive material disposed in the interconnected voids and extending between, and forming part of, the first and second major surfaces; and
a plurality of electrically conductive first particles dispersed in the interconnected voids, wherein at least some of the conductive segments and first particles at least partially protrude through each of the first and second major surfaces of the base layer.

2. The electrically conductive adhesive film of claim 1, wherein the adhesive material fills greater than about 30 percent of a total volume of the interconnected voids between the first and second major surfaces.

3. The electrically conductive adhesive film of claim 1 further comprising a plurality of resiliently compressible polymeric second particles different from the first particles and dispersed in the interconnected voids, such that when, in response to a first compressive force, the base layer is compressed by more than about 30% of its uncompressed average thickness, the base layer regains at least about 60% of its uncompressed average thickness after the first compressive force is removed.

4. The electrically conductive adhesive film of claim 3, wherein at least a majority of the resiliently compressible polymeric second particles are electrically insulative hollow particles.

5. The electrically conductive adhesive film of claim 1 further comprising an electrically conductive self-supporting support layer electrically conductive in the thickness direction and each of mutually orthogonal in-plane first and second directions, the support layer disposed on and bonded to the base layer so that an electrically conductive major surface of the support layer makes electrical and physical contact with some of the conductive segments and with at least one of the electrically conductive first particles.

6. An electronic device comprising a first of the electrically conductive adhesive film of claim 1 disposed between, and bonding and electrically connecting to, first and second electrically conductive components of the electronic device.

7. An electrically conductive resiliently compressible adhesive film comprising:
an electrically conductive spongy layer having an uncompressed average thickness of greater than about 30 microns and electrically conductive along at least a thickness direction thereof, the spongy layer comprising an electrically conductive sponge material defining a plurality of interconnected pores;
an adhesive material disposed in the pores to form an adhesive layer comprising opposing external first and second major surfaces of the adhesive film, portions of the electrically conductive sponge material protruding through each of the first and second major surfaces of the adhesive layer; and
a plurality of resiliently compressible polymeric particles dispersed in the pores, such that when the adhesive film is disposed between, and bonded to, first and second electrically conductive gold layers to form a compressible structure, an electrical resistance between the first and second gold layers is less than about 0.5 ohms and varies by less than about 50% when the compressible structure is compressed from no more than about 10 percent compression to least about 30 percent compression.

8. The electrically conductive resiliently compressible adhesive film of claim 7, wherein the resiliently compressible polymeric particles are electrically insulative.

9. The electrically conductive resiliently compressible adhesive film of claim 8 further comprising a plurality of electrically conductive particles dispersed in the adhesive layer, at least some of the electrically conductive particles at least partially protrude through each of the first and second major surfaces of the adhesive film.

10. An adhesive tape comprising the electrically conductive resiliently compressible adhesive film of claim 7 bonded to an electrically conductive self-supporting support layer electrically conductive in the thickness direction and each of mutually orthogonal in-plane first and second directions, an electrically conductive major surface of the support layer making electrical and physical contact with portions of the electrically conductive sponge material.

11. A display comprising:
a display panel configured to form a viewable image and drivable by receiving electrical signals from an electronic circuit, the electronic circuit comprising a first flexible circuit comprising electrically conductive first and second traces disposed on opposing major sides of a first flexible film;
an electrically conductive substrate comprising an electrically conductive outermost surface;
and a first of the electrically conductive resiliently compressible adhesive film of claim 7 disposed between the first flexible circuit and the electrically conductive substrate, such that:
the first major surface of the first adhesive film is bonded, and makes physical and electrical contact, to the second trace of the first flexible circuit; and
the second major surface of the first adhesive film is bonded, and makes physical and electrical contact, to the electrically conductive outermost surface of the electrically conductive substrate.

12. An electrically conductive adhesive film comprising an electrically conductive porous spongy layer defining a plurality of interconnected pores and having an uncompressed average thickness of greater than about 30 microns, the spongy layer comprising an electrically insulative sponge material coated with an electrically conductive material resulting in the spongy layer being electrically conductive along a thickness direction thereof and along each of mutually orthogonal first and second in-plane directions, an adhesive material disposed in the pores in the plurality of the interconnected pores to form an adhesive layer comprising opposing external first and second major surfaces of the adhesive film, portions of the sponge material protruding through each of the first and second major surfaces of the adhesive layer.

13. The electrically conductive adhesive film of claim 12 further comprising a plurality of resiliently compressible polymeric particles dispersed in the pores.

14. An electrically conductive resiliently compressible adhesive film comprising:
an electrically conductive porous spongy layer defining a plurality of interconnected pores and having an uncompressed average thickness of greater than about 30 microns, the spongy layer comprising an electrically insulative sponge material coated with an electrically conductive material resulting in the spongy layer being electrically conductive along a thickness direction thereof and along each of mutually orthogonal first and second in-plane directions; and
a plurality of resiliently compressible polymeric particles dispersed in the pores.

15. The electrically conductive resiliently compressible adhesive film of claim 14 further comprising an adhesive material disposed in the pores in the plurality of the interconnected pores to form an adhesive layer comprising opposing external first and second major surfaces of the adhesive film, portions of the sponge material protruding through each of the first and second major surfaces of the adhesive layer.
